(19) United States
(12) Patent Application Publication
(10) Pub. No.: US 2024/0292715 A1
(43) Pub. Date: Aug. 29, 2024

(54) DISPLAY PANEL AND DISPLAY DEVICE

(71) Applicant: WUHAN CHINA STAR OPTOELECTRONICS SEMICONDUCTOR DISPLAY TECHNOLOGY CO., LTD., Wuhan (CN)

(72) Inventor: Fei QI, Wuhan (CN)

(73) Assignee: WUHAN CHINA STAR OPTOELECTRONICS SEMICONDUCTOR DISPLAY TECHNOLOGY CO., LTD., Wuhan (CN)

(21) Appl. No.: 18/496,890

(22) Filed: Oct. 29, 2023

(30) Foreign Application Priority Data
Feb. 24, 2023 (CN) 202320318039.2

(51) Int. Cl. H10K 59/80

(52) U.S. Cl. CPC H10K 59/8731; H10K 59/879

(57) ABSTRACT

A display panel includes a light-emitting device and an encapsulating member. The encapsulating member includes a first inorganic encapsulating layer, which includes at least a first inorganic encapsulating sub-layer and a second inorganic encapsulating sub-layer that are stacked in a direction away from the light-emitting device. The first inorganic encapsulating sub-layer is disposed on one side of the second inorganic encapsulating sub-layer close to the light-emitting device. The thickness of the first inorganic encapsulating sub-layer is greater than that of the second inorganic encapsulating sub-layer. The refractive index of the first inorganic encapsulating sub-layer is n1, the refractive index of the second inorganic encapsulating sub-layer is n2, wherein n1>n2. The extinction coefficient of the first inorganic encapsulating sub-layer is less than 0.001.

### CROSS-REFERENCE TO RELATED APPLICATION

The present disclosure claims priority to and the benefit of Chinese Patent Application No. 202320318039.2, filed on Feb. 24, 2023, the disclosure of which is incorporated herein by reference in its entirety.

### TECHNICAL FIELD

The present disclosure relates to the field of display technology, and more particularly, to a display panel and a display device.

### BACKGROUND

For organic light-emitting diode (OLED) products, in order to ensure that the encapsulating member for encapsulating a light-emitting device has a higher transmittance, the inorganic encapsulating sub-layer in a first inorganic encapsulating layer of the encapsulating member that is closest to the light-emitting device and plays a regulating role has a low refractive index, since an inorganic film with a lower refractive index generally has higher oxygen content, the inorganic encapsulating sub-layer to have poor water-oxygen barrier ability, and water and oxygen directly enters and passes through the inorganic encapsulating sub-layer with weak water-oxygen barrier ability through the side of the screen body, which easily leads to encapsulating failure.

### SUMMARY

The embodiments of the present disclosure provide a display panel and a display device, so as to solve the technical problem that an inorganic encapsulating sub-layer of a first inorganic encapsulating layer of an existing display panel and an encapsulating member of the display device has a poor water-oxygen barrier ability, which easily leads to encapsulating failure.

In order to solve the above problems, the technical solutions provided by the present disclosure are as follows.

The present disclosure provides a display panel including:
a light-emitting device; and
an encapsulating member disposed on the light-emitting device for encapsulating the light-emitting device, wherein the encapsulating member includes a first inorganic encapsulating layer, the first inorganic encapsulating layer includes at least a first inorganic encapsulating sub-layer and a second inorganic encapsulating sub-layer that are stacked in a direction away from the light-emitting device, and the first inorganic encapsulating sub-layer is disposed on one side of the second inorganic encapsulating sub-layer close to the light-emitting device.

A thickness of the first inorganic encapsulating sub-layer is greater than a thickness of the second inorganic encapsulating sub-layer; a refractive index of the first inorganic encapsulating sub-layer is n1, a refractive index of the second inorganic encapsulating sub-layer is n2, wherein n1>n2, and an extinction coefficient of the first inorganic encapsulating sub-layer is less than 0.001. According to the display panel provided by the present disclosure, n1>1.7.

According to the display panel provided by the present disclosure, n2>1.62.

According to the display panel provided by the present disclosure, 1.62<n2<1.76.

According to the display panel provided by the present disclosure, the light-emitting device includes a first electrode, a second electrode, and a light-emitting layer disposed between the first electrode and the second electrode, and the second electrode is closer to the encapsulating member than the first electrode.

The display panel further includes an organic light-gathering layer disposed on one side of the second electrode away from the light-emitting device.

According to the display panel provided by the present disclosure, the display panel further includes an optical compensation layer disposed between the organic light-gathering layer and the encapsulating member.

A refractive index of the optical compensation layer is n3, wherein n3<n2.

According to the display panel provided by the present disclosure, a material of the optical compensation layer includes lithium fluoride.

According to the display panel provided by the present disclosure, materials of the first inorganic encapsulating sub-layer and the second inorganic encapsulating sub-layer include silicon oxynitride.

According to the display panel provided by the present disclosure, the display panel further includes an organic encapsulating layer and a second inorganic encapsulating layer, wherein the organic encapsulating layer is disposed on one side of the first inorganic encapsulating layer away from the light-emitting device, and the second inorganic encapsulating layer is disposed on one side of the organic encapsulating layer away from the light-emitting device.

The present disclosure provides a display device including the above display panels.

The beneficial effects of the present disclosure are as follows: According to the display panel and the display device provided in the present disclosure, the first inorganic encapsulating layer of the encapsulating member includes at least a first inorganic encapsulating sub-layer and a second inorganic encapsulating sub-layer that are stacked in a direction away from the light-emitting device. Compared with the related arts, in which one inorganic encapsulating sub-layer that plays a regulating role is disposed on the side of the inorganic encapsulating sub-layer (namely, the first inorganic encapsulating sub-layer) that plays the main encapsulating role and is close to the light-emitting device; in the present disclosure, a first inorganic encapsulating sub-layer is disposed on the side of the second inorganic encapsulating sub-layer close to the light-emitting device, that is, the first inorganic encapsulating sub-layer is disposed at the lowermost layer of the first inorganic encapsulating layer. Further, the refractive index n1 of the first inorganic encapsulating sub-layer is controlled to be greater than the refractive index n2 of the second inorganic encapsulating sub-layer, so as to ensure that the water-oxygen barrier ability of the first inorganic encapsulating layer can be improved, thereby improving the encapsulating performance of the encapsulating member. Meanwhile, the extinction coefficient of the first inorganic encapsulating sub-layer is controlled to be less than 0.001, which can ensure the encapsulating performance of the encapsulating member, and ensure the light transmittance of the encapsulating member.

### BRIEF DESCRIPTION OF THE DRAWINGS

In order to more clearly describe the technical solutions in the embodiments of the present disclosure, hereinafter, the appended drawings used for describing the specific embodiments will be briefly introduced. Apparently, the appended drawings described below are only directed to some embodiments of the present disclosure, and for a person skilled in the art, without expenditure of creative labor, other drawings can be derived on the basis of these appended drawings.

FIG. 1 is a schematic diagram of a cross-sectional configuration of a display panel according to some embodiments of the present disclosure.

FIG. 2 is a schematic diagram showing a relationship between the relative white light efficiency of a light-emitting device and an extinction coefficient of a first inorganic encapsulating sub-layer according to some embodiments of the present disclosure.

FIG. 3 is a schematic diagram showing a relationship between color difference between a central area and an edge area of a display panel and the refractive index of a second inorganic encapsulating sub-layer according to some embodiments of the present disclosure.

FIG. 4 is a schematic diagram of a cross-sectional configuration of another display panel according to some embodiments of the present disclosure.

### LIST OF REFERENCE SIGNS

1: Light-emitting device; 11: first electrode; 12: light-emitting layer; 13: second electrode; 2: encapsulating member; 21: first inorganic encapsulating layer; 211. first inorganic encapsulating sub-layer; 212. second inorganic encapsulating sub-layer; 22. second inorganic encapsulating layer; 23. organic encapsulating layer; 3. organic light-gathering layer; 4. optical compensation layer.

### DETAILED DESCRIPTION

Hereinafter, technical solution in embodiments of the present disclosure will be clearly and completely described with reference to the accompanying drawings in embodiments of the present disclosure. Obviously, the described embodiments are part of, but not all of, the embodiments of the present disclosure. All the other embodiments, obtained by a person with ordinary skill in the art on the basis of the embodiments in the present disclosure without expenditure of creative labor, belong to the protection scope of the present disclosure. In addition, it should be understood that specific embodiments described herein are only used to illustrate and explain the present disclosure, and are not intended to limit the present disclosure. In the present disclosure, unless otherwise stated, orientation words such as “up” and “down” generally refers to “up” and “down” in the actual use or working state of a device, and exemplarily refers to the drawing direction in the drawings; while “inside” and “outside” refer to outline of a device.

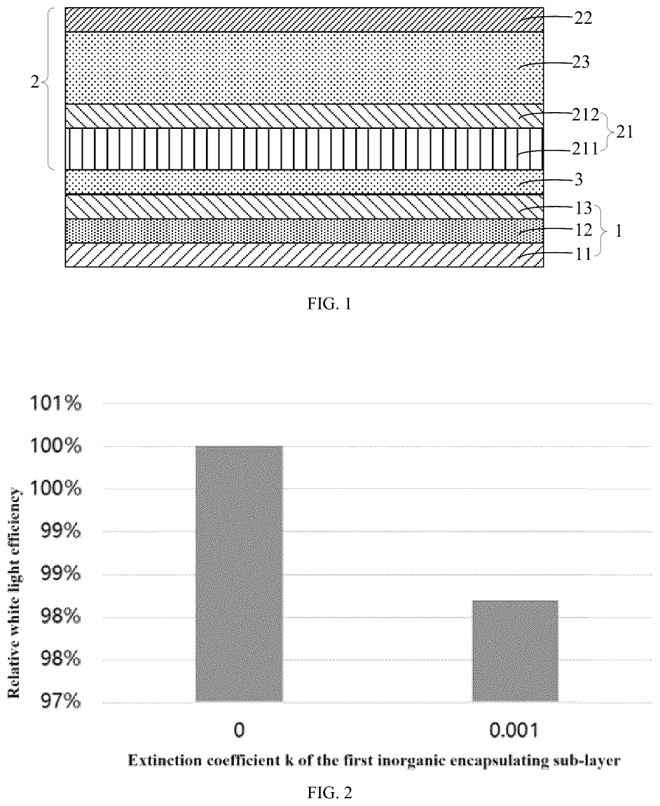

Referring to FIG. 1, which is a schematic diagram of a cross-sectional configuration of a display panel according to some embodiments of the present disclosure. Embodiments of the present disclosure provide a display panel, which may include one of an organic light-emitting diode display panel and a quantum dot light-emitting diode.

The display panel includes a light-emitting device 1 and an encapsulating member 2. The encapsulating member 2 is disposed on the light-emitting device 1 for encapsulating the light-emitting device 1. The light-emitting device 1 includes a plurality of light-emitting pixels for emitting light, and the plurality of light-emitting pixels may include red light-emitting pixels, green light-emitting pixels, blue light-emitting pixels, and white light-emitting pixels. The encapsulating member 2 covers the plurality of light-emitting pixels to prevent external water and oxygen from invading the plurality of light-emitting pixels, thereby avoiding failure of the organic light-emitting material in the light-emitting pixels and causing poor display.

The display panel further includes a driving device (not shown in the figure), which is located on one side of the light-emitting device 1 away from the encapsulating member 2. The driving device includes a plurality of driving circuits corresponding to and electrically connected to the plurality of light-emitting pixels for driving the plurality of light-emitting pixels to realize light emitting and displaying. The driving circuits include a plurality of thin film transistors, which may include driving thin film transistors for controlling the light-emitting pixels and switching thin film transistors for switching the driving thin film transistors. A thin film transistor may include a semiconductor layer, a gate, a source, and a drain, wherein the semiconductor layer may be formed of an inorganic semiconductor or an organic semiconductor. A driving device further includes an insulating film layer such as a gate insulating layer, an interlayer dielectric layer, a passivation layer, and a planarization layer. As related arts, details are not described herein.

The encapsulating member 2 may adopt a film encapsulating mode. The encapsulating member 2 may adopt an inorganic encapsulating stack or an inorganic-organic-inorganic multi-layer encapsulating stack. In the embodiments of the present disclosure, the encapsulating member 2 includes a first inorganic encapsulating layer 21, and the first inorganic encapsulating layer 21 is an inorganic encapsulating layer close to the light-emitting device 1. The first inorganic encapsulating layer 21 includes a first inorganic encapsulating sub-layer 211 and a second inorganic encapsulating sub-layer 212 that are stacked in a direction away from the light-emitting device 1. The first inorganic encapsulating sub-layer 211 is disposed the side of the second inorganic encapsulating sub-layer close to the light-emitting device 1.

The first inorganic encapsulating sub-layer 211 is the encapsulating sub-layer that plays the main encapsulating role in the first inorganic encapsulating layer 21. The second inorganic encapsulating sub-layer 212 is the encapsulating sub-layer that plays a regulating role in the first inorganic encapsulating layer 21. Since the inorganic film with a lower refractive index generally has higher oxygen content and lower water-oxygen barrier ability, it is particularly important for the first inorganic encapsulating sub-layer 212 in the present disclosure to have a high refractive index.

In the present disclosure, the thickness of the first inorganic encapsulating sub-layer 211 is greater than the thickness of the second inorganic encapsulating sub-layer 212, the refractive index of the first inorganic encapsulating sub-layer 211 is n1, and the refractive index of the second inorganic encapsulating sub-layer 212 is n2, wherein n1>n2, so as to ensure that the water-oxygen barrier ability of the first inorganic encapsulating layer 21 is improved, thereby improving the encapsulating performance of the encapsulating member 2. Meanwhile, the extinction coefficient of the first inorganic encapsulating sub-layer 211 is less than 0.001. By controlling the extinction coefficient of the first inorganic encapsulating sub-layer 211, the light transmittance of the encapsulating member 2 can be ensured, and the encapsulating performance of the encapsulating member 2 can also be ensured.

Referring to FIG. 2, which is a schematic diagram showing a relationship between the relative white light efficiency of the light-emitting device and an extinction coefficient of a first inorganic encapsulating sub-layer according to some embodiments of the present disclosure. The relative white light efficiency of a light-emitting device 1 and the extinction coefficient k of the first inorganic encapsulating sub-layer 211 is shown in FIG. 2. It can be seen from FIG. 2 that when the extinction coefficient k of the first inorganic encapsulating sub-layer 211 increases from 0 to 0.001, and the white light efficiency of the light-emitting device 1 decreases by about 2%. Therefore, in order to ensure the display efficiency of the light-emitting device 1, in the embodiments of the present disclosure, the extinction coefficient k of the first inorganic encapsulating sub-layer 211 is controlled to be less than 0.001, that is, k<0.001.

Understandably, please continue to refer to FIG. 1, the design logic of the technical solutions provided by the present disclosure is described as follows.

In the related arts, one inorganic encapsulating sub-layer that plays a regulating role is disposed on the side of the inorganic encapsulating sub-layer (namely, the first inorganic encapsulating sub-layer 211) that plays the main encapsulating role and is close to the light-emitting device 1 in the first inorganic encapsulating layer 21. In contrast, in the present disclosure, inorganic encapsulating sub-layer that plays a regulating role is not disposed on the side of the first inorganic encapsulating sub-layer 211 close to the light-emitting device 1. The first inorganic encapsulating sub-layer 211 is directly used as the lowermost layer of the first inorganic encapsulating layer 21, that is, the first inorganic encapsulating sub-layer 211 is directly used as the lowermost layer of the encapsulating member 2. Meanwhile, the first inorganic encapsulating sub-layer 211 is controlled to have a high refractive index, so that the encapsulating performance of the first inorganic encapsulating sub-layer 211 is better, thereby overcoming the disadvantage of poor water-oxygen barrier ability of the first inorganic encapsulating layer 21 in the related arts. However, a problem of decrease in the light transmittance of the first inorganic encapsulating sub-layer 211 arises at the same time due to high refractive index of the first inorganic encapsulating sub-layer 211. In order to overcome this problem, a relatively low extinction coefficient of the first inorganic encapsulating sub-layer 211 is controlled in the present disclosure. The smaller the extinction coefficient, the smaller the loss of light. That is, the light transmittance of the first inorganic encapsulating sub-layer 211 is increased in the present disclosure, thereby improving the light transmittance of the encapsulating member 2. Therefore, the technical solutions provided by the present disclosure can simultaneously ensure the encapsulating performance and the light transmittance of the encapsulating member 2.

In order to ensure the barrier ability, the first inorganic encapsulating sub-layer 211 has a large thickness, and the thickness of the first inorganic encapsulating sub-layer 211 is greater than 500 nanometers. For example, the thickness of the first inorganic encapsulating sub-layer 211 may be one of 510 nm, 520 nm, 550 nm, and 600 nm. The second inorganic encapsulating sub-layer 212 is a regulating layer and does not need to be too thick. The thickness of the second inorganic encapsulating sub-layer 212 ranges from 10 nm to 200 nm. For example, the thickness of the second inorganic encapsulating sub-layer 212 may be one of 10 nm, 50 nm, 100 nm, 150 nm, and 200 nm.

Referring to Table 1 below, the difference between the refractive index n1 of the first inorganic encapsulating sub-layer 211 and the encapsulating performance of the encapsulating member 2 can be seen. In the present disclosure, the first inorganic encapsulating sub-layer 211 and the second inorganic encapsulating sub-layer 212 with different refractive indices are combined to perform a WHTS measurement test on the light-emitting device 1. It should be noted that the WHTS measurement test is a storage test under high temperature and high humidity conditions, which means that the display panel is placed in an oven at a temperature of about 85° C. and a humidity of about 85% for several hours to qualitatively evaluate whether dark spots and the like appear. The relationship between the light-emitting device 1 passing the test and the refractive index n1 of the first inorganic encapsulating sub-layer 211 is shown in Table 1 below, and are described below in detail:

In the case that the refractive index n1 of the first inorganic encapsulating sub-layer 211 is 1.62, the display panel fails to pass the 120 h storage test, that is, encapsulating failure occurs. In the case that the refractive index n1 of the first inorganic encapsulating sub-layer 211 is 1.7, the display panel passes the 120 h storage test, but fails to pass the 240 h storage test. In the case that the refractive index n1 of the first inorganic encapsulating sub-layer 211 is 1.77, the display panel passes both the 120 h storage test and the 240 h storage test. In the case that the refractive index n1 of the first inorganic encapsulating sub-layer 211 is 1.81, the display panel passes the 120 h storage test, the 240 h storage test and the 360 h storage test. It should be noted that “NG” in Table 1 indicates that the display panel fails to pass the storage test of a corresponding time, and “PASS” means that the display panel passes the storage test of a corresponding time.

It can be seen that, with the increase of the refractive index n1 of the first inorganic encapsulating sub-layer 211 increases, the display panel can pass the storage test for a longer time. That is, the encapsulating performance of the encapsulating member 2 is improved, and the reliability of the display panel is also improved.

Therefore, in order to ensure the encapsulating performance of the encapsulating member 2 and the reliability of the display panel, in the embodiments of the present disclosure, the refractive index n1 of the first inorganic encapsulating sub-layer 211 is controlled to satisfy the following relationship: n1>1.7.

TABLE 1

85° C., 85 RH

| n1 | 120 h | 240 h | 360 h |
|---|---|---|---|
| 1.62 | NG | | |
| 1.7 | PASS | NG | |
| 1.76 | PASS | PASS | NG |
| 1.81 | PASS | PASS | PASS |

Since the first inorganic encapsulating layer 21 is generally prepared by a chemical vapor deposition (CVD) method containing a mask, the inorganic film deposited by this method generally has a problem of poor uniformity. Particularly, the film thickness difference between the edge of the screen and the central area of the screen is large, which causes the phenomena of green or pink appearing at the edge of the screen. Therefore, in order to avoid the phenomena of green or pink appearing at the edge of the screen, the refractive index of the second inorganic encapsulating layer is controlled to be greater than 1.62 in the present disclosure.

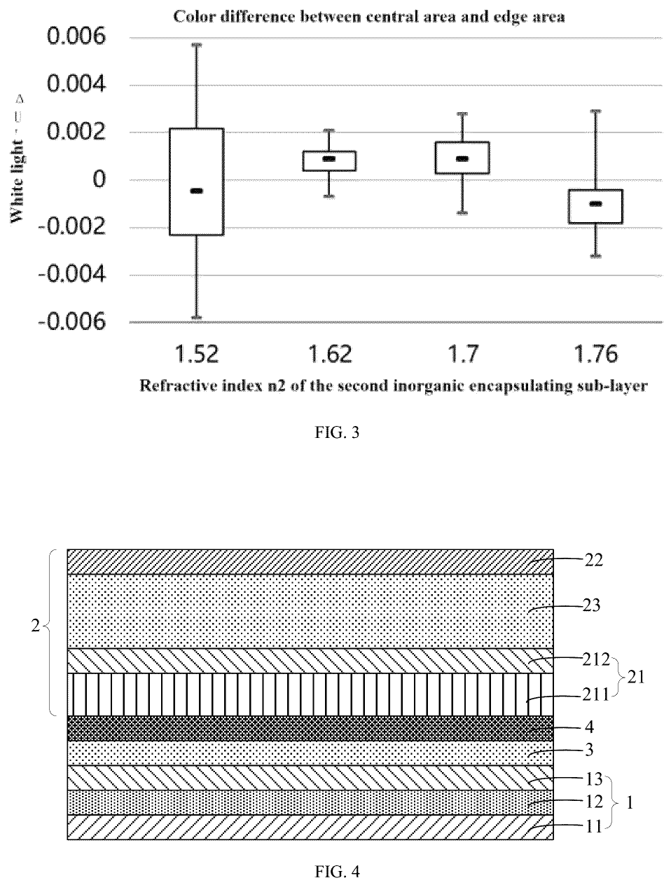

Further, referring to FIG. 3, which is a schematic diagram showing a relationship between color difference between a central area and an edge area of a display panel and the refractive index of a second inorganic encapsulating sub-layer according to some embodiments of the present disclosure. When the light-emitting device 1 displays white light, the color difference Δu′ between the central area and the edge area of the light-emitting device 1 is measured. The relationship between the fluctuation range of Δu′ and n of the second inorganic encapsulating sub-layer 212 is shown in FIG. 3. As can be seen from FIG. 3, in the case that the refractive index n2 of the second inorganic encapsulating sub-layer 212 is 1.52, the fluctuation range of Δu′ is large, and the maximum value is close to ±0.006, indicating that the color difference between the central area and the edge area of the light-emitting device 1 is large, and the phenomenon of green or pink appearing at the edge of the screen is serious. In the case that the refractive index n2 of the second inorganic encapsulating sub-layer 212 increases to 1.62/1.7, the fluctuation range of Δu′ is significantly reduced. In the case that the refractive index n2 of the second inorganic encapsulating sub-layer 212 continues to increase to 1.76, the fluctuation range of Δu′ increases again, but is still smaller than the fluctuation range in the case that n2=1.52. Therefore, in order to ensure the chromaticity uniformity of the light-emitting device 1, the refractive index n2 of the second inorganic encapsulating sub-layer 212 should be controlled between 1.62 and 1.76, that is, 1.62<n2<1.76.

Exemplarily, the light-emitting device 1 includes a first electrode 11, a second electrode 13, and a light-emitting layer 12 disposed between the first electrode 11 and the second electrode 13. The second electrode 13 is disposed closer to the encapsulating member 2 than the first electrode 11. In an embodiment, the display panel further includes an organic light-gathering layer 3, which is disposed between the optical compensation layer 4 and the second electrode 13. The organic light-gathering layer 3 has a high refractive index, and light emitted from the light-emitting device 1 is converged after passing through the organic light-gathering layer 3, so that the light-gathering purpose is achieved by reducing the light emission angle.

The first electrode 11 may be one of an anode or a cathode, and the second electrode 13 is another of an anode or a cathode. In the embodiments of the present disclosure, the display panel is a top-emitting display panel, the first electrode 11 is an anode, and the second electrode 13 is a cathode. The first electrode 11 may include Ag, Mg. Al, Pt, Pd, Au, Ni, Nd, Ir, Cr, or a mixture of these metals. The second electrode 13 may include a transparent metal oxide such as indium tin oxide (ITO), indium zinc oxide (IZO), zinc oxide (ZnO), and indium tin zinc oxide (ITZO). Of course, the light-emitting device 1 further includes a pixel definition layer which defines a plurality of pixel openings, the pixel openings expose the anode, and the light-emitting layer 12 is disposed in the pixel openings.

In some embodiments, referring to FIG. 4, which is a schematic diagram of a cross-sectional configuration of another display panel according to some embodiments of the present disclosure. FIG. 4 is different from FIG. 1 in that the display panel further includes an optical compensation layer 4 disposed between the organic light-gathering layer 3 and the encapsulating member 2. The refractive index of the optical compensation layer 4 is n3, wherein n3<n2. The reason for this setting is that the optical compensation layer 4 is made of a material with a certain water-oxygen barrier ability, and the refractive index of the optical compensation layer 4 is smaller than that of the second inorganic encapsulating sub-layer 212, that is, the optical compensation layer 4 has a lower refractive index, and the optical compensation layer 4 has a certain encapsulating performance, which can compensate for the optical influence caused by canceling the inorganic encapsulating sub-layer with a low refractive index on the side of the first inorganic encapsulating sub-layer 211 close to the light-emitting device 1.

Further, the optical compensation layer 4 is made of a transparent material to avoid reducing the light-emitting efficiency of the light-emitting device 1.

Optionally, in the embodiments of the present disclosure, the material of the optical compensation layer 4 includes lithium fluoride.

Exemplarily, the thickness of the optical compensation layer 4 is less than 100 nm. Optionally, the thickness of the optical compensation layer 4 may be one of 90 nm, 80 nm, 70 nm, 60 nm, 50 nm, 40 nm, 30 nm, 20 nm, 10 nm.

In some embodiments, the materials of the first inorganic encapsulating sub-layer 211 and the second inorganic encapsulating sub-layer 212 include silicon oxynitride.

In some embodiments, the display panel further includes an organic encapsulating layer 23 and a second inorganic encapsulating layer. The organic encapsulating layer 23 is disposed on one side of the first inorganic encapsulating layer 21 away from the light-emitting device 1. The second inorganic encapsulating layer 22 is disposed on one side of the organic encapsulating layer 23 away from the light-emitting device 1. The organic encapsulating layer 23 may include an organic material, for example, acrylic resin, epoxy resin, polyimide, and polyethylene, but is not limited thereto.

Of course, in other embodiments, in order to obtain better encapsulating performance, the display panel may further include more organic encapsulating layers 23 and inorganic encapsulating layers disposed on the side of the second inorganic encapsulating layer away from the light-emitting device 1, and the present disclosure is not limited thereto.

The embodiments of the present disclosure further provide a display device including the display panel in the above-described embodiments. The display device may include a movable display device (such as a notebook computer, a mobile phone, and the like), a fixed terminal (such as a desktop computer, a television, and the like), a measuring device (such as a sports bracelet, a thermometer, and the like), and the like.

The present disclosure provides a display panel and a display device. According to the display panel and the display device provided in the present disclosure, the first inorganic encapsulating layer of the encapsulating member includes at least a first inorganic encapsulating sub-layer and a second inorganic encapsulating sub-layer that are stacked in a direction away from the light-emitting device. Compared with the related arts, in which one inorganic encapsulating sub-layer that plays a regulating role is disposed on the side of the inorganic encapsulating sub-layer (namely, the first inorganic encapsulating sub-layer) that plays the main encapsulating role and is close to the light-emitting device; in the present disclosure, a first inorganic encapsulating sub-layer is disposed on the side of the second inorganic encapsulating sub-layer close to the light-emitting device, that is, the first inorganic encapsulating sub-layer is disposed at the lowermost layer of the first inorganic encapsulating layer. Further, the refractive index n1 of the first inorganic encapsulating sub-layer is controlled to be greater than the refractive index n2 of the second inorganic encapsulating sub-layer, so as to ensure that the water-oxygen barrier ability of the first inorganic encapsulating layer can be improved, thereby improving the encapsulating performance of the encapsulating member. Meanwhile, the extinction coefficient of the first inorganic encapsulating sub-layer is controlled to be less than 0.001, which can ensure the encapsulating performance of the encapsulating member, and ensure the light transmittance of the encapsulating member.

In view of above, although the present disclosure has been disclosed above in terms of preferred embodiments, the above preferred embodiments are not intended to limit the present disclosure. Those skilled in the art may make can make various changes and modifications without departing from the spirit and scope of the present disclosure, so the scope of protection of the present disclosure shall be subject to the scope defined by the claims.

What is claimed is:

1. A display panel, comprising:
a light-emitting device; and
an encapsulating member disposed on the light-emitting device for encapsulating the light-emitting device, the encapsulating member comprising a first inorganic encapsulating layer, the first inorganic encapsulating layer comprising at least a first inorganic encapsulating sub-layer and a second inorganic encapsulating sub-layer that are stacked in a direction away from the light-emitting device, and the first inorganic encapsulating sub-layer being disposed on one side of the second inorganic encapsulating sub-layer close to the light-emitting device;
wherein a thickness of the first inorganic encapsulating sub-layer is greater than a thickness of the second inorganic encapsulating sub-layer; a refractive index of the first inorganic encapsulating sub-layer is n1, a refractive index of the second inorganic encapsulating sub-layer is n2, wherein n1>n2, and an extinction coefficient of the first inorganic encapsulating sub-layer is less than 0.001.

2. The display panel according to claim 1, wherein n1>1.7.

3. The display panel according to claim 2, wherein n2>1.62.

4. The display panel according to claim 3, wherein 1.62<n2<1.76.

5. The display panel according to claim 1, wherein the light-emitting device comprises a first electrode, a second electrode, and a light-emitting layer disposed between the first electrode and the second electrode, and the second electrode is closer to the encapsulating member than the first electrode; and
wherein the display panel further comprises an organic light-gathering layer disposed on one side of the second electrode away from the light-emitting device.

6. The display panel according to claim 5, further comprising an optical compensation layer disposed between the organic light-gathering layer and the encapsulating member;
wherein a refractive index of the optical compensation layer is n3, and n3<n2.

7. The display panel according to claim 6, wherein a material of the optical compensation layer comprises lithium fluoride.

8. The display panel according to claim 1, wherein materials of the first inorganic encapsulating sub-layer and the second inorganic encapsulating sub-layer comprise silicon oxynitride.

9. The display panel according to claim 1, further comprising an organic encapsulating layer and a second inorganic encapsulating layer, wherein the organic encapsulating layer is disposed on one side of the first inorganic encapsulating layer away from the light-emitting device, and the second inorganic encapsulating layer is disposed on one side of the organic encapsulating layer away from the light-emitting device.

10. The display panel according to claim 2, wherein the light-emitting device comprises a first electrode, a second electrode, and a light-emitting layer disposed between the first electrode and the second electrode, and the second electrode is closer to the encapsulating member than the first electrode; and
wherein the display panel further comprises an organic light-gathering layer disposed on one side of the second electrode away from the light-emitting device.

11. The display panel according to claim 10, further comprising an optical compensation layer disposed between the organic light-gathering layer and the encapsulating member;
wherein a refractive index of the optical compensation layer is n3, and n3<n2.

12. A display device comprising a display panel, wherein the display panel comprises:
a light-emitting device; and
an encapsulating member disposed on the light-emitting device for encapsulating the light-emitting device, the encapsulating member comprising a first inorganic encapsulating layer, the first inorganic encapsulating layer comprising at least a first inorganic encapsulating sub-layer and a second inorganic encapsulating sub-layer that are stacked in a direction away from the light-emitting device, and the first inorganic encapsulating sub-layer being disposed on one side of the second inorganic encapsulating sub-layer close to the light-emitting device;
wherein a thickness of the first inorganic encapsulating sub-layer is greater than a thickness of the second inorganic encapsulating sub-layer; a refractive index of the first inorganic encapsulating sub-layer is n1, a refractive index of the second inorganic encapsulating sub-layer is n2, wherein n1>n2, and an extinction coefficient of the first inorganic encapsulating sub-layer is less than 0.001.

13. The display panel according to claim 12, wherein n1>1.7.

14. The display panel according to claim 13, wherein n2>1.62.

15. The display panel according to claim 14, wherein 1.62<n2<1.76.

16. The display panel according to claim 12, wherein the light-emitting device comprises a first electrode, a second electrode, and a light-emitting layer disposed between the first electrode and the second electrode, and the second electrode is closer to the encapsulating member than the first electrode; and
wherein the display panel further comprises an organic light-gathering layer disposed on one side of the second electrode away from the light-emitting device.

17. The display panel according to claim 16, further comprising an optical compensation layer disposed between the organic light-gathering layer and the encapsulating member;
wherein a refractive index of the optical compensation layer is n3, and n3<n2.

18. The display panel according to claim 17, wherein a material of the optical compensation layer comprises lithium fluoride.

19. The display panel according to claim 12, wherein materials of the first inorganic encapsulating sub-layer and the second inorganic encapsulating sub-layer comprise silicon oxynitride.

20. The display panel according to claim 12, further comprising an organic encapsulating layer and a second inorganic encapsulating layer, wherein the organic encapsulating layer is disposed on one side of the first inorganic encapsulating layer away from the light-emitting device, and the second inorganic encapsulating layer is disposed on one side of the organic encapsulating layer away from the light-emitting device.
